(19) United States
(12) Patent Application Publication
(10) Pub. No.: US 2025/0233073 A1
(43) Pub. Date: Jul. 17, 2025

(54) LOW RESISTIVITY TUNGSTEN INTERCONNECT STRUCTURES

(71) Applicant: VEECO INSTRUMENTS INC., Plainview, NY (US)

(72) Inventors: Rutvik J. MEHTA, Plainview, NY (US); Yuejing WANG, Plainview, NY (US); Robert CALDWELL, Plainview, NY (US); Frank CERIO, Plainview, NY (US)

(21) Appl. No.: 19/023,213

(22) Filed: Jan. 15, 2025

Related U.S. Application Data
(60) Provisional application No. 63/621,212, filed on Jan. 16, 2024.

(51) Int. Cl. H01L 23/532; H01L 21/768

(52) U.S. Cl. CPC H01L 23/53257; H01L 21/76859

(57) ABSTRACT

Ion beam deposition processes, with assist or etch, that produce a tungsten interconnect and an inserted layer that can have a graduated composition in contact with an underlayer. The interconnect has the desirable alpha phase of the tungsten layer and a microstructure with highly oriented (110) grains with at least 95%, or at least 99% or 99.9% and even 100%, of the deposited tungsten thin film having a (110) crystalline orientation plane, relative to the top surface of the film.

### CROSS-REFERENCE

This application claims priority to U.S. provisional application No. 63/621,212 filed Jan. 16, 2024, the entire disclosure of which is incorporated herein by reference for all purposes.

### BACKGROUND

Modern electronic integrated circuits for memory applications such as Dynamic Random Access Memory (DRAM), Flash Memory, and Phase-change Random Access Memory (PCRAM), and microprocessors such as central processing units (CPU) and graphic processing units (GPU), contain multiple electrically conductive interconnect layers that are arranged at high density and fine pitch. As the electronic devices scale further in the nanometer era, a key technological enabler is the means to create smaller and finer interconnect structures that possess high electrical conductivity, that is, low electrical resistivity. As an example, for DRAM devices, advanced technological nodes require shrinking both the dimensions of the interconnect structures as the device scales down and simultaneously maintaining the low electrical resistivity. However, current technology is not able to provide the desired structures and this inability detrimentally affects the memory performance and inhibits scaling of DRAM, thus proving to be technological bottlenecks.

The interconnect structures are made of metallic elements or alloys. Major technological barriers affecting the interconnect performance include the phenomenon of the resistivity of metals increasing as physical dimensions such as length, width and height of the wires approach or become smaller than the electron mean free path, and the necessity of many metallic interconnect structures requiring critical template layers or adhesion layers or barrier layers which are difficult to shrink and scale down. The size-dependent resistivity increase originates primarily through increased electron scattering at the metal surfaces and layer boundaries and is exacerbated by increased scattering from not only surface roughness but also at grain boundaries of the polycrystalline structure of the metal which typically becomes finer with downscaling. The resistivity increase is a major challenge particularly for continued down scaling of the most critical and smallest interconnects in integrated circuits. The necessity of template layers or adhesion layers or barrier layers, collectively referred to as template layers, originates in the limitation of many conventional deposition technologies such as Physical Vapor Deposition (PVD) including Magnetron Sputtering PVD, RF Sputtering PVD and others, Chemical Vapor Deposition (CVD) and Atomic Layer Deposition (ALD) of being unable to control the nucleation, growth, phase, crystalline structure, texture and microstructure of the metallic films without the presence of appropriate such template layers of particular thickness. This results in challenges for continued down scaling of the most critical and smallest interconnects in integrated circuits as the template layers cannot be shrunk without degradation of the metallic interconnect layer resistivity.

Typical metals used for interconnect structures include aluminum (Al), copper (Cu), tungsten (W), ruthenium (Ru), molybdenum (Mo), cobalt (Co), and others.

Refractory metals such as tungsten (W) are of great interest for certain interconnect structures in DRAM memory, other types of memory and advanced logic devices due to the relatively small electronic mean free path, favorable scaling of the resistivity with dimensional shrinkage, high resistance to electromigration and high resistance to oxidation. Additionally, tungsten demonstrates a size-dependent anisotropic electrical resistivity where the normally isotropic resistivity shows a dependence on the crystalline structure which intrinsically relates to the grain texture, orientation, and epitaxy of polycrystalline films. Modeling and experimental work in the literature show that for body-centered cubic (BCC) Alpha tungsten, (110) orientation with conduction along the (110) planes, that is, (110) planes oriented parallel to the film surface, is the most favorable for low resistivity. In general, it is well known in the literature that the resistivity of metal films is intimately correlated with the microstructure due to the influence on the electron scattering mechanics. The microstructure, which can be described through parameters such as the grain size distribution characteristics of grain shape, grain size, grain volume, grain boundaries with variable spacing and their frequencies, grain boundary characteristics such as small and high angle boundaries, and grain orientation such as the orientation of the dominant poles and planes of the grains. As such, for tungsten thin films used for interconnect structures, the lowest resistivities are achievable through depositing and growing tungsten by various methods that result in thin films with alpha BCC tungsten with (110) orientation of planes with the largest grain sizes, most homogeneous grain size distribution and low angle grain boundaries.

However, optimizing the microstructures of metal thin films to achieve the lowest resistivity can be very challenging. It is well known in the literature that metal thin films nucleation, growth and microstructures are strongly dependent on the template layers and their structure and thickness as these template layers influence the sticking coefficient of sputtered or reacted metal atoms, metal adatom mobility, surface energetics and kinetics, growth mode such as islanding, layer-by-layer or mixed mode, and crystalline strain, stress, and reconstruction. Thus, as is also well-known in the literature, thin film growth and hence thin film properties are a strong and complex function of the metal being deposited, template layer composition, template layer thickness, deposition temperature, and surface chemistry. For many common interconnect structures, it is desirable to create a structure of a metal such as tungsten deposited on layers collectively referred to as underlayers, such as metals such as titanium or tantalum or semiconducting layers such as silicon or metal nitride layers such as titanium nitride (TiN), silicon nitride (SiN), tungsten nitride (WN) or other dielectrics layers such a silicon oxide and other metal oxides. However, direct deposition of tungsten onto these desirable underlayers by conventional methods such as PVD, CVD, ALD result in the creation of a metastable beta-phase tungsten instead of the desired alpha BCC tungsten and concomitant unfavorable microstructures having high resistivity. As a result, conventional methods and prior art heretofore use relatively thick template layers of amorphous silicides such as tungsten silicides (WSiₓ) and tungsten silicon nitrides (WSiNₓ), of as much as 50 Å thickness, inserted between the underlayer and tungsten. These template layers are typically deposited using the similar conventional technologies of PVD, CVD, ALD in separate chambers; that is, the template layers are deposited first on the underlayers in one chamber followed by deposition of the tungsten layer on the template layer in a different, separate chamber. These template layers, as described earlier, are a critical hurdle to integrated circuit shrinkage and technological advances.

### SUMMARY

The present disclosure is directed to methods of forming interconnect structures of low resistivity tungsten, for memory and logic integrated circuits, by ion beam deposition (IBD). The interconnect structures have a low resistivity tungsten layer deposited by IBD on a desirable underlayer that can include metallic layers, such as titanium or tantalum, semiconducting layers such as silicon, dielectrics such as metal nitride layers that include titanium nitride (TiN), silicon nitride (SiN), titanium silicon nitride (TiSiN), tungsten nitride (WN), tungsten silicon nitride (WSiN) or tantalum nitride (TaN), any of which may be deposited by PVD, CVD, ALD and IBD; if deposited via IBD, it can be deposited in the same chamber as the tungsten layer. The methods for creating the interconnect structures include depositing tungsten metal onto the underlayer via ion beam deposition with assist etch, in a process chamber with a multi-target turret at a deposition temperature not higher than 450° C. The tungsten film may be no thicker than 50 nm, in some embodiment no thicker than 40 nm.

In some embodiments, the interconnect structure has the low resistivity tungsten layer on the underlayer without a layer in between the tungsten layer and the underlayer; that is, the tungsten is in contact with the underlayer.

For such interconnect structures, a method of creation includes first depositing an in-situ (that is, in the same chamber) a single sacrificial layer using IBD, which is removed in a subsequent single step or multiple steps by being consumed using IBD with assist or by etching using the assist etch followed by final deposition of the tungsten film layer using IBD. Such a method utilizes an IBD with assist system having a multi-target turret containing both a tungsten target and other target materials with a composition matching the requirements for the sacrificial layer.

In other embodiments, the interconnect structure is created by using multiple sacrificial layers on or over the underlayer. For such interconnect structures, the method of creation includes first depositing, in-situ (that is, in the same chamber), a first sacrificial layer using IBD, followed by a second sacrificial layer and additional sacrificial layers as required, which are removed in subsequent single step or multiple steps by being consumed using IBD with assist or by etching using the assist etch. After the sacrificial layers have been completely removed or consumed, a tungsten film layer is deposited using IBD with assist on the underlayer to yield the interconnect structure having the low resistivity tungsten layer on the underlayer without a layer in between the tungsten layer and the underlayer. The sacrificial layers may be same or different and composed of elements or materials.

In another embodiment, the method of creation such an interconnect structure includes first depositing, in-situ, on the underlayer, a tungsten sacrificial layer using IBD, which is removed in a subsequent single step or multiple steps by being consumed using IBD with assist or by etching using the assist etch followed by final deposition of remaining thickness of the tungsten film layer using IBD with assist.

For these methods for creating the interconnect structure, the methods utilize IBD with assist with the ion beam deposition chamber with a multi-target turret containing at least a tungsten target.

In other embodiments, the interconnect structure has the low resistivity tungsten layer, the underlayer and a thin layer, referred to as inserted layer, between the tungsten layer and the underlayer. In some embodiments, the tungsten layer is in contact with the inserted layer on one side of the inserted layer and the underlayer is in contact with the inserted layer on an opposite side of the inserted layer.

For such interconnect structures, a method of creation includes first depositing an in-situ layer using IBD or IBD with assist, the thickness of which can be varied, followed by a subsequent single step or multiple steps of depositing a one or more sacrificial layers using IBD with or without assist followed by sequences of using the assist etch for altering the thickness of the inserted layer and consuming and etching the sacrificial layers followed by deposition of remaining thickness of the tungsten film layer using IBD. The sacrificial layer(s) are composed of materials such as metals, dielectrics or semiconductors which are same of different from the inserted layer.

The inserted layer can have a composition based on the multiple targets that are present in the multi-target turret of the process chamber. Alternately, the inserted layer can have a compositional gradient with the composition of the film and alloy or compound formed from the multiple targets varying through the thickness of the film. For example, the composition of the inserted layer varies from high amount of one constituent and low amount of another from the bottom which is in contact with the underlayer through and to low amount of the one constituent and high amount of the other at the top which is in contact with the tungsten layer. Additionally or alternately, the inserted layer composition can be modified in-situ to be different from that of the target used for the deposition thereof. A compositional gradient or modification implies a change in the composition of the inserted layer, example materials not limited to metal alloys such as W—Ti alloys, or dielectrics such as nitrides such as titanium nitride or silicon nitride or silicides such as tungsten silicide. As a result, the method for making the inserted layer can be used to create an in-situ dielectric layer such as an in-situ nitride or in-situ silicide with a graded composition or a varying composition.

In all of the embodiments of this disclosure, the underlayer is an electrically conducting metal or a semiconductor or a dielectric. Examples of metallic layers include titanium and tantalum, and semiconducting layers include silicon, metal nitride layers such as titanium nitride (TiN), silicon nitride (SiN), titanium silicon nitride (TiSiN), tungsten nitride (WN), tungsten silicon nitride (WSiN) and tantalum nitride (TaN). The thickness of this underlayer is no greater than 150 Å, in some embodiments no greater than 50 Å, and in other embodiments no greater than 40 Å.

The inserted layer can be composed of elements such as semiconductors such as silicon, metals such as titanium, tantalum, tungsten and others or dielectrics such as oxides including silicon oxide, tungsten oxide, titanium oxide, nitrides such as silicon nitride, titanium nitride, tungsten nitride, silicide-nitrides such as titanium silicon nitride, tungsten silicon nitride, silicides such as tungsten silicide, titanium silicide and others. The thickness of the inserted layer can be varied, e.g., from less than 5 Å to as thick as 35 Å; the inserted layer is typically no thicker than 50 Å.

The sacrificial layer can be an electrical conductor (metal), a semiconductor, or an insulator (dielectric). Examples of suitable materials for a sacrificial layer include semiconductors such as silicon, metals such as titanium, tantalum, tungsten and others, dielectrics such as oxides including silicon oxide, tungsten oxide and titanium oxide, nitrides such as silicon nitride, titanium nitride, and tungsten nitride, silicide-nitrides such as titanium silicon nitride, silicides such as tungsten silicide, titanium silicide, and others.

When forming an interconnect structure, the sacrificial layer(s) can be the same or different from the inserted layer.

One particular method described herein for forming a low resistivity interconnect structure comprises depositing an underlayer on a substrate using ion beam deposition in a process chamber, the underlayer having a thickness less than 150 Å and being a semiconductor, a metal, or a dielectric, and after depositing the underlayer, depositing a tungsten film using ion beam deposition in the process chamber at a temperature of no more than 450° C. using a tungsten target held in a multi-target turret in the process chamber.

A resulting thin tungsten film, made by any of the methods herein, can have alpha BCC large and highly oriented (110) grains with at least 95%, often at least 99% and even 99.9% or 100%, of the deposited tungsten thin film having a (110) crystalline orientation plane, relative to the top surface of the film. The thickness of the tungsten film can be less than or no thicker than 50 nm (500 Å), in some embodiments less than or no thicker than 40 nm (400 Å) or 35 nm (350 Å). The grain size distribution can be such that the average grain size is at least five times, and more than ten times, the film thickness in the as-deposited state without additional annealing. Additionally, the resulting thin tungsten interconnect structure can have a low resistivity at different thickness, for example, less than 7 μΩ-cm for film thickness of 50 nm and thicker, less than 8 μΩ-cm for film thickness of 35 nm and thicker, less than 9 μΩ-cm for film thickness of 20 nm and thicker, less than 11 μΩ-cm for film thickness of 10 nm and thicker or less than 20 μΩ-cm for film thickness of 2 nm and thicker.

This Summary is provided to introduce a selection of concepts in a simplified form that are further described below in the Detailed Description. This Summary is not intended to identify key or essential features of the claimed subject matter, nor is it intended to be used to limit the scope of the claimed subject matter. These and various other features and advantages will be apparent from a reading of the following Detailed Description.

### BRIEF DESCRIPTION OF THE DRAWING

FIG. 1A is a schematic circuit diagram of a DRAM memory cell; FIG. 1B is a schematic circuit diagram of a logic device wiring scheme.

FIG. 2A through 2D are schematic side views of a DRAM Bit Line stack, such as from the DRAM memory cell of FIG. 1A, including the interconnect structure having a low resistivity tungsten thin film in accordance with one or more embodiments of the present disclosure; FIG. 2A illustrates an interconnect structure without an inserted layer; FIG. 2B illustrates an interconnect structure with a thin inserted layer; FIG. 2C illustrates an interconnect structure with an inserted layer with modified composition; and FIG. 2D illustrates an interconnect structure with an inserted layer with graded composition from bottom to top.

FIGS. 3A through 3D are schematic side views of a logic device interconnection stack, such as from the logic device of FIG. 1B, including the interconnect structure having the low resistivity tungsten thin film in accordance with one or more embodiments of the present disclosure; FIG. 3A illustrates an interconnect structure without an inserted layer; FIG. 3B illustrates an interconnect structure with a thin inserted layer; FIG. 3C illustrates the interconnect structure with an inserted layer with modified composition; and FIG. 3D illustrates the interconnect structure with an inserted layer with graded composition from bottom to top.

FIG. 4 is a flowchart showing, stepwise, a method for depositing an interconnect structure having a low resistivity tungsten on an underlayer without a layer in between the tungsten layer and the underlayer.

FIG. 5 is a schematic diagram showing, in side view, a stepwise method for depositing an interconnect structure having a low resistivity tungsten on an underlayer without a layer in between the tungsten layer and the underlayer.

FIG. 6 is a flowchart showing, stepwise, a method for depositing an interconnect structure having a low resistivity tungsten on an underlayer with a thin inserted layer in between the tungsten layer and the underlayer.

FIG. 7 is a schematic diagram showing, in side view, a stepwise method for depositing an interconnect structure with a low resistivity tungsten on an underlayer with a thin inserted layer in between the tungsten layer and the underlayer.

FIG. 8 is a flowchart showing, stepwise, a method for depositing an interconnect structure having a low resistivity tungsten on an underlayer with a thin inserted layer in between the tungsten layer and the underlayer where the inserted layer composition is graded from bottom to the top.

FIG. 9 is a schematic diagram showing, in side view, a stepwise method for depositing an interconnect structure having a low resistivity tungsten on an underlayer with a thin inserted layer in between the tungsten layer and the underlayer where the inserted layer composition is graded from bottom to the top.

FIG. 10A is a graphical illustration of resistivity versus thickness scaling relationship for a low resistivity tungsten interconnect structure; FIG. 10B is a schematic diagram of an interconnect structure having a low resistivity tungsten on an underlayer without an insertion layer in between the tungsten layer and the underlayer; FIG. 10C is a schematic diagram of an interconnect structure having a low resistivity tungsten on an underlayer with an insertion layer in between the tungsten layer and the underlayer.

### DETAILED DESCRIPTION

As indicated above, this disclosure is directed to methods of making a low resistivity tungsten interconnect, and the various structures made thereby.

In the following description, reference is made to the accompanying drawing that forms a part hereof and in which is shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples, including the figures, provided below. In some instances, a reference numeral may have an associated sub-label consisting of a lower-case letter to denote one of multiple similar components. When reference is made to a reference numeral without specification of a sub-label, the reference is intended to refer to all such multiple similar components.

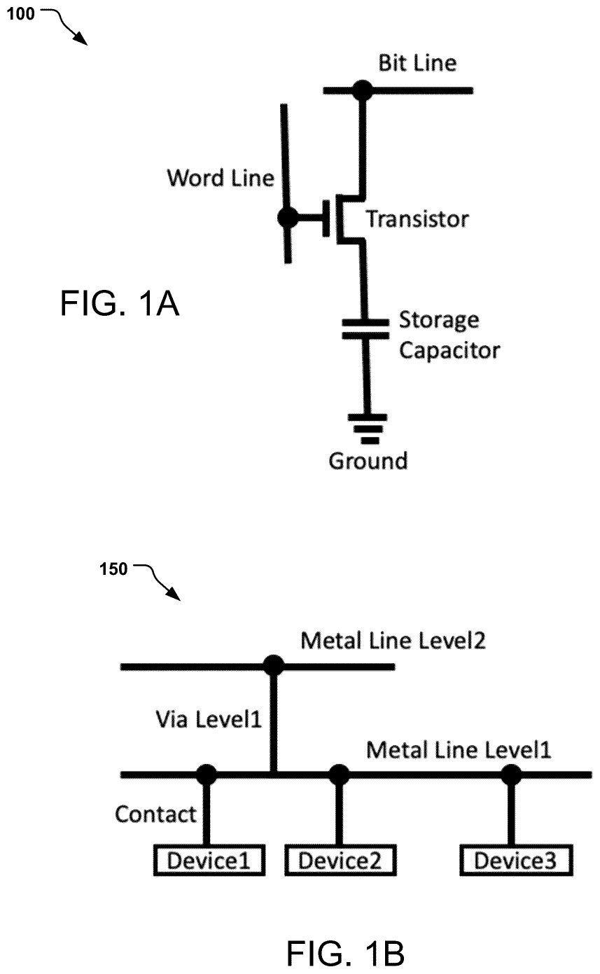

Turning to the figures, FIG. 1A illustrates a circuit diagram of a DRAM memory cell 100 having a one-transistor-one-capacitor scheme used in most DRAM cells where the metallic interconnects lines such as the Bit Line and Word Line, amongst others, are used to connect the devices that make up the cell. The Bit Line connects the source of the transistor and the Word Line connects the gate of the transistor for multiple memory cells of the memory chip. The Bit Line and the Word Line are the primary interconnects used to convey power and signals to the memory cells. Generally, DRAM memory utilizes tungsten metal lines for these interconnects.

FIG. 1B illustrates a circuit diagram of a logic device wiring scheme 150 where the metallic interconnects connect multiple devices, which may be different devices. The wiring scheme 150 includes multiple metallic layers, such as Metal Line Level 1 that connects the contacts to the devices (Device1, Device2, Device3) and Metal Line Level 2 that connects to the Metal Line Level 1 through a via such as a Via Level 1.

A logic chip such as a microprocessor has multiple such metallic interconnect levels; the number of interconnect levels is often up to the dozens. Typically, the interconnects used for memory (e.g., memory cell 100 of FIG. 1A), logic devices (e.g., device 150 of FIG. 1B) and other chips are made with metals that are deposited as thin films onto various underlayers. The underlayers serve many roles, such as diffusion barriers, adhesion liners, contact enhancers, etc., and are an integral component of the devices.

Generally, logic chips utilize copper metals for the interconnects, especially for the higher levels. Copper, however, has several limitations, including steeply increasing resistivity with decreasing dimensions of the wires. Especially when deposited on the underlayer, the metal for the wiring and interconnect schemes needs low resistivity.

Metals as an alternate to copper have been considered, including tungsten, molybdenum, ruthenium and cobalt, amongst others. Tungsten is an attractive choice for metallic wiring due to its high melting point as a refractory metal, relatively smaller mean free path for conduction electrons (which results in a favorable scaling of the resistivity with dimensional shrinking), high resistance to electromigration, resistance to oxidation, low resistivity, and ease of processing. Tungsten, however, has a complex behavior during its deposition and the resulting thin film. While bulk tungsten has low resistivity, due to its body centered cubic (BCC) structure (sometimes referred to as alpha phase or structure), in thin films tungsten can exhibit a metastable high resistivity simple cubic (SC) structure (sometimes referred to as beta phase or beta structure).

This beta phase of tungsten is susceptible to forming on common underlayers such as titanium and especially on dielectrics such as nitrides of metals such as titanium nitride, silicon nitride, tungsten nitride and also oxides such as silicon oxides. Avoiding this beta structure requires complex processing steps during the fabrication of the interconnects used in memory and logic chips; steps such as the use of additional inserted layers such as tungsten silicides, tungsten nitrides or tungsten silicon nitrides, typically having a thickness of 2 nm to 5 nm or more. These inserted layers increase the total thickness of the interconnect and thus the total dimension of the interconnect, counteracting the trend of shrinking devices for integrated circuits. Additionally, as the dimensions of the interconnects shrink, the inserted layers become a larger fraction of the total size, significantly degrading the interconnect performance. It is difficult to reduce the thickness of the inserted layers because, as the layers decrease in thickness, they are not able to suppress the formation of the tungsten beta phase and/or promote the formation of the desired low-resistivity tungsten alpha phase.

Additionally, to attain low resistivity of tungsten, a microstructure with 110dominant orientation of grains is required, as the 110 orientation has the lowest resistivity due to the size dependent anisotropy in the tungsten resistivity. The formation of 110 microstructures is challenging on the underlayers due to the formation of the beta phase.

Thin film deposition techniques such as magnetron plasma vapor deposition (PVD), radio frequency PVD, chemical vapor deposition (CVD), atomic layer deposition (ALD) and others are unable to deposit tungsten on underlayers without inserted layers on or between the underlayers. Ion beam deposition (IBD), however, is useful for depositing thin films with the highest energy, at reduced pressures, and with control of deposition geometry, which can produce layers with higher crystallinity and with controlled microstructures.

IBD systems are well known. IBD systems have a vacuum chamber equipped with a fixture for holding a substrate such as a wafer, with capability of rotating and heating the wafer and, even in some embodiments, tilting the wafer. The chamber has an ion beam source (deposition ion beam source) which is used to sputter a target material which deposits on the substrate. The target can be held in a multi-target turret, which can accommodate targets of different materials. The chamber also has a second ion beam source which directs an ion beam (assist ion beam) at the wafer for assisting and etching the thin film as it is deposited.

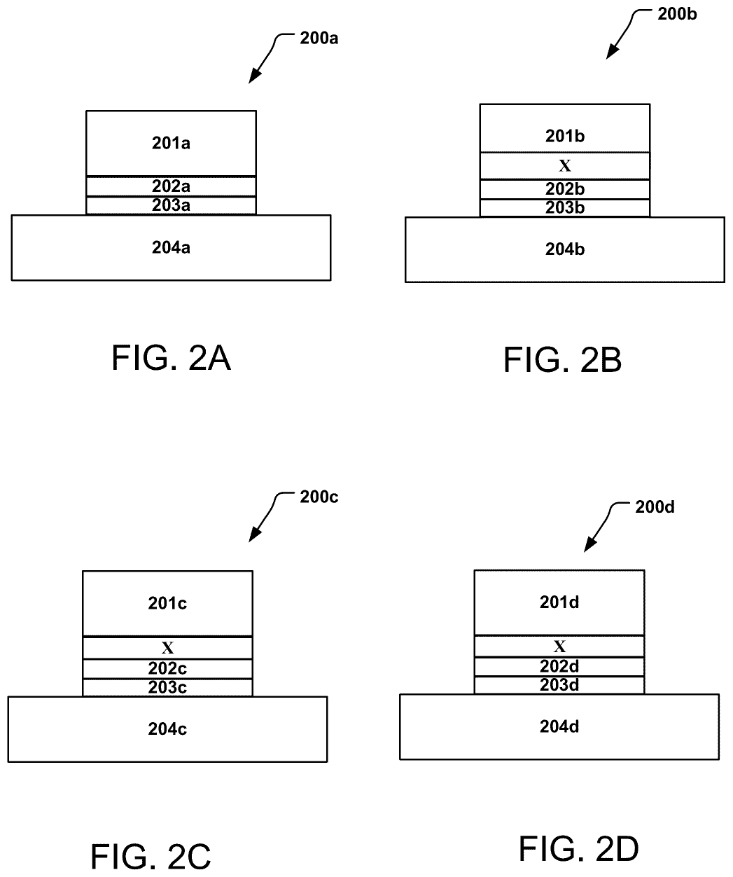

Using the methods described herein, high quality, low resistivity interconnect structures for memory cells, such as the DRAM Bit Line such as shown in FIG. 1A, can be made with IBD. FIGS. 2A through 2D show various interconnect structures where a low resistivity tungsten layer is deposited on a desirable underlayer that is formed on a contact layer in contact with a transistor.

In a device 200a of FIG. 2A, a tungsten layer 201a is in direct contact with an underlayer 202a without the presence of an inserted layer. The underlayer 202a is on a contact layer 203a that is connected to a transistor 204a.

In FIG. 2B, a device 200b has a tungsten layer 201b, an underlayer 202b on a contact layer 203b that is connected to a transistor 204b. In this structure, an inserted layer x is present between the tungsten layer 201b and the underlayer 202b. The inserted layer x is thin (e.g., less than 2 nm, in some cases as thin as 1.5 nm, and can be as thin as 1 nm, 0.5 nm and even as thin as 0.3 nm).

This interconnect structure 200b is formed using ion beam deposition with the inserted layer x deposited on the underlayer 202b followed by deposition of the low resistivity tungsten layer 201b. The inserted layer x is formed in-situ in the same chamber using ion beam deposition and ion beam assist.

Similarly, in FIG. 2C, a device 200c has a tungsten layer 201c, an underlayer 202c on a contact layer 203c that is connected to a transistor 204c. An inserted layer x is present between the tungsten layer 201c and the underlayer 202c. In this structure 200c, the composition of the inserted layer x in the final device 200c is different from the composition of a sacrificial inserted layer that was used to form the inserted layer x.

As before, this interconnect structure 200c is formed using ion beam deposition with the inserted layer x deposited on the underlayer 202c followed by deposition of the low resistivity tungsten layer 201c. The inserted layer x is formed in-situ in the same chamber using ion beam deposition and ion beam assist but with a different target used for the insertion layer x than the targets used in deposition. By utilizing a multi-turret target holder, the composition of the inserted layer x can be adjusted as desired, in-situ, without changing the target or changing gas or other materials used in the deposition.

A device 200d in FIG. 2D has a tungsten layer 201d, an underlayer 202d on a contact layer 203d that is connected to a transistor 204d. An inserted layer x is present between the tungsten layer 201d and the underlayer 202d. In this structure 200d, the composition of the inserted layer x is varied and is graduated from the bottom to the top. Further, this composition is different from the composition of the other layers. This is due to the target(s) used for the inserted layer x being different than the target(s) used for the deposition. The graduated composition is created, in-situ, without changing the target, the processing gas or other materials used in the deposition.

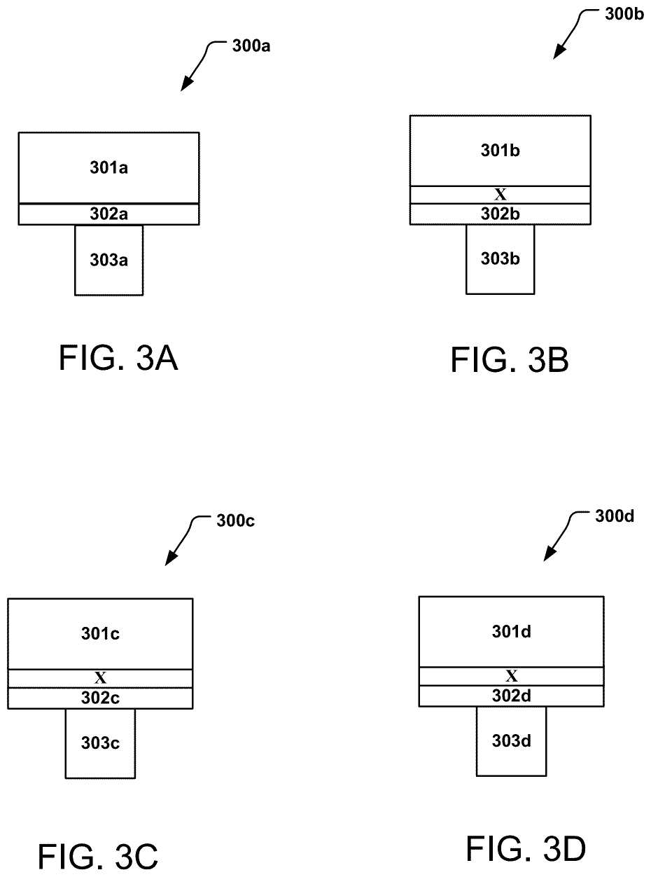

In a similar fashion, interconnect structures for logic devices such as device 150 of FIG. 1B can be made with IBD. In FIGS. 3A through 3D, a low resistivity tungsten layer is deposited on a desirable underlayer that is present on a connection layer, such as a contact layer, operably in contact with and connected to a device or a Via Level 1 as shown in FIG. 1B.

In a device 300a of FIG. 3A, a tungsten layer 301a is in direct contact with an underlayer 302a without the presence of an inserted layer. The underlayer 302a is operably in contact with a connection layer 303a.

In FIG. 3B, an interconnect structure 300b has a tungsten layer 301b separated from an underlayer 302b by an inserted layer x. The underlayer 302b is operably in contact with a connection layer 303b. The inserted layer x is thin (e.g., less than 2 nm, in some cases as thin as 1.5 nm or 1 nm or 0.5 m, and even as thin as 0.3 nm). The inserted layer x is formed in-situ in the same chamber as the tungsten layer 301b and the connection layer 303b, using ion beam deposition and ion beam assist.

In FIG. 3C, an interconnect structure 300c has a thin inserted layer x between a tungsten layer 301c and an underlayer 302c where the composition of the inserted layer x is modified from that which was originally deposited. The underlayer 302c is operably in contact with a connection layer 303c.

The inserted layer x is formed in-situ in the same chamber as the layers 301c, 302c using ion beam deposition and ion beam assist but with a different target used for the insertion layer x than the targets used for the deposition of the other layers. By utilizing a multi-turret target holder, the composition of the inserted layer x can be adjusted as desired, in-situ, without changing the target or changing gas or other materials used in the deposition.

In FIG. 3D, an interconnect structure 300d has a thin inserted layer x between a tungsten layer 301d and an underlayer 302d where the composition of the inserted layer x is different from that of the tungsten layer 301d and the underlayer 302d. The underlayer 302d is operably in contact with a connection layer 303d. In this structure, the composition of the inserted layer x is varied and is graduated from the bottom to the top. Further, this composition is different from the composition of the other layers 301d, 302d. This is due to the target(s) used for the inserted layer x being different than the target(s) used for the deposition. The graduated composition is created, in-situ, without changing the target, the processing gas or other materials used in the deposition.

In all of the structures of FIGS. 2A to 2D and 3A to 3D, the tungsten layer 201, 301 is pure tungsten (at least 99% tungsten, in some embodiments at least 99.9% tungsten) is alpha phase with a microstructure of highly oriented grains with at least 95%, in some embodiments at least 99% or at least 99.9%, and in other embodiments 100% of the grains in the (110) orientation. The thickness of the tungsten layers 201, 301 may be less than or no thicker than 50 nm (500 Å), in some embodiments less than or no thicker than 40 nm (400 Å), and in other embodiments less than or no thicker than 35 nm (350 Å).

The underlayers 202, 302 are thin films of electrically conductive materials such as metals such as titanium or tantalum or semiconducting layers such as silicon or dielectrics such as metal nitride layers, which can include titanium nitride (TiN), silicon nitride (SiN), tungsten nitride (WN) or other dielectrics such a silicon oxide and other metal oxides. The thickness of the underlayers 202, 302 is no greater than 150 Å, in some embodiments no greater than 50 Å.

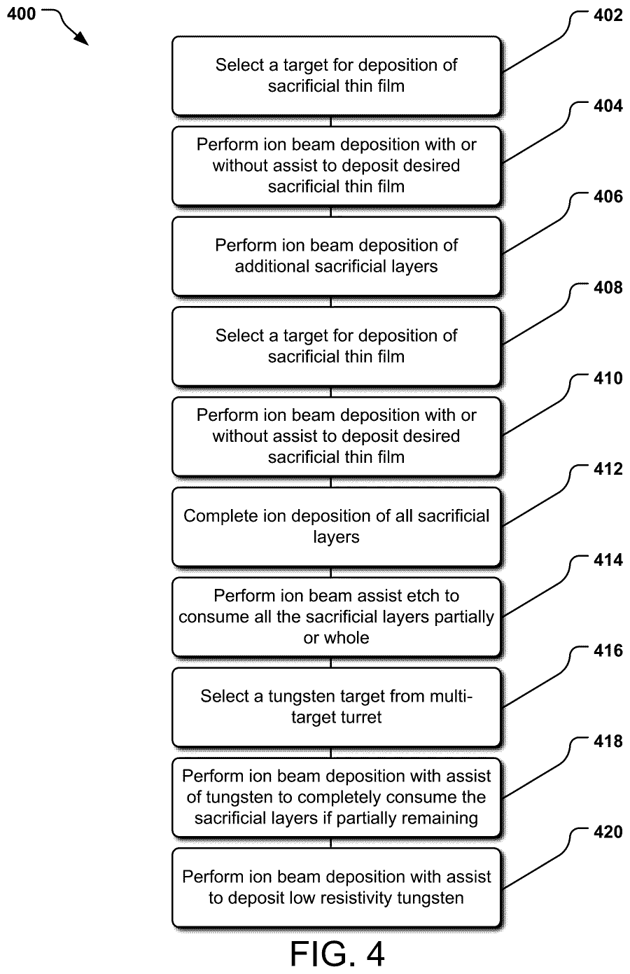

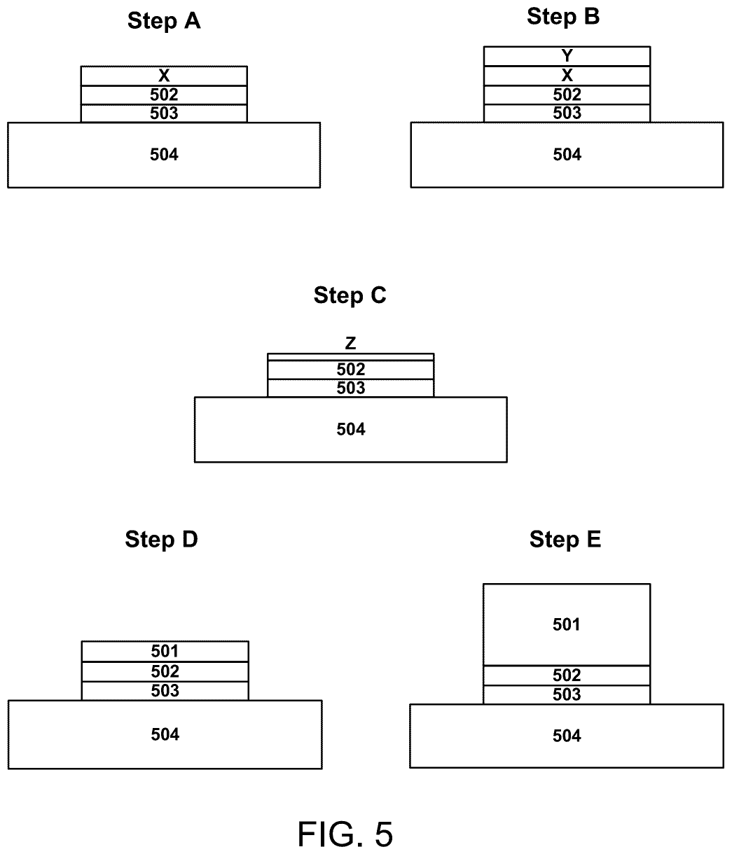

FIG. 4 describes, step by step, a method of making a structure such as the interconnect structures for memory and logic integrated circuits as described in FIG. 2A and FIG. 3A, and FIG. 5 illustrates schematically the configuration of the structures, step by step. The resulting structures have a thin inserted layer between the low resistivity tungsten layer and the underlayer.

Referring to FIG. 4, a multi-step method 400 is shown. In a first step 402, a target in an IBD system is selected for use in depositing a sacrificial thin film; this target may be one of many targets in a multi-target turret. An ion beam deposition is done in step 404 to deposit the sacrificial thin film on a substrate; this may be done with or without assist. Any additional sacrificial layers or thin films can be deposited in step 406 in a manner similar to steps 402, 404.

In step 408, another target is selected for use in depositing another sacrificial thin film; this target may be one of many targets in the multi-target turret. An ion beam deposition is done in step 410 to deposit this sacrificial thin film on the previous sacrificial thin film(s) on the substrate; this may be done with or without assist. Any additional sacrificial layers or thin films can be deposited, and in step 412, all sacrificial layers having been deposited via ion deposition, with or without assist. In step 414, ion beam assist etching is performed to remove portions or all of the sacrificial layer(s).

In step 416, a tungsten target is selected for use in depositing a tungsten thin film in step 418 with ion beam deposition with assist; any remaining sacrificial layers may be completely removed. After all sacrificial layers are removed, ion beam deposition with assist is continued in step 420 to deposit a low resistivity tungsten film.

In FIG. 5, the evolution of the structure made via the method 400 of FIG. 4 is shown stepwise. In FIG. 5, layer 501 represents a tungsten layer, the layer 502 represents a desirable underlayer thin film, and the layer 503 represents other layers that are part of the device structure, such as a contact layer, for example, and structure 504 represents the device or structure in a DRAM memory cell or other type of memory cell or logic integrated circuit. Layers X and Y are sacrificial layers.

Referring back to FIG. 4, step 402 selects a target material from the multi-target turret of the ion beam deposition chamber; this target is used to deposit the sacrificial thin film layer X shown in Step A in FIG. 5 on the underlayer 502 via step 404. The thickness of the sacrificial layer X may be, e.g., as thin as 0.5 nm and as thick as 2 nm. Either this single sacrificial layer X or additional multiple sacrificial layers may be deposited, as per step 406. For a single sacrificial layer X, the next step would be to proceed to the structure of Step C. For additional sacrificial layers, the next step is to select another target material, as per step 408, from the multi-target and then deposit the sacrificial layer Y (per step 410) using ion beam deposition as shown in Step B of FIG. 5. The thickness of the sacrificial layer Y may be, e.g., as thin as 0.5 nm and as thick as 2 nm.

The process used to deposit the sacrificial layers may be ion beam deposition using only the deposition ion beam or ion beam deposition with assist using both the deposition and assist ion beams. Ion beam energies of at least 50V to as high as 2000V can be used and ion beam current of at least 50 mA to as high as 2000 mA can be used.

After all the sacrificial layers have been deposited as per step 412, the sacrificial layers are consumed (removed) using the assist ion beam in step 414, and as shown in Step C of FIG. 5, to etch the films and intermix the atoms of the different layers. Ion beam energies of at least 50V to as high as 2000V can be used and ion beam current of at least 50 mA to as high as 2000 mA can be used, but are typically on the lower end for the consumption. The use of the assist ion beam consumes the sacrificial layers X, Y and any others completely by etching and intermixing and, in doing so, modifies the surface chemistry of the underlayer 502 without causing any damage. Alternately, the sacrificial layer(s) are partially consumed by etching and intermixing leaving behind a sacrificed layer Z having a thickness as low as 0.1 nm and no more than 2 nm. Step C of FIG. 5 shows a partially consumed sacrificial layer Z; if the sacrificial layer was fully consumed, layer Z would not be present.

For partially consumed and sacrificed thin films, as seen in Step C, in the next Step D of FIG. 5 corresponding to step 416 of FIG. 4, the tungsten target is selected and used to deposit a tungsten thin film using ion beam deposition with assist. With the appropriate choice of assist and deposition beam conditions, the partially consumed sacrificial layers are fully consumed (step 418), resulting in no inserted layers between the deposited tungsten layer 501 and the underlayer 502. Finally in Step E of FIG. 5 and step 420, the tungsten thin film 501 is deposited by ion beam deposition with assist to the desired thickness. For sacrificial layers which are completely consumed in Step C (thus no layer Z existing), Step D is skipped and the tungsten film is deposited to the desired thickness using ion beam deposition with assist in Step E. Ion beam energies of at least 50V to as high as 2000V can be used and ion beam current of at least 50 mA to as high as 2000 mA can be used.

The sacrificial layer or layers X, Y, Z, etc. may be thin films of metals such as titanium and tungsten, semiconductors such as silicon, dielectrics such as silicon oxide and silicon nitride, silicides such as tungsten silicide, or silicon nitrides such as tungsten silicon nitride.

In one particular implementation of the process, a single sacrificial layer of tungsten is deposited and consumed, followed by deposition of the low resistivity tungsten in a self-sacrificial process to form the interconnect structure where the tungsten is in direct contact with the underlayer without an inserted layer.

In another particular implementation of the process, a first sacrificial layer of silicon is deposited followed by a second sacrificial layer of tungsten, which layers are then completely consumed. Subsequently, deposition of the low resistivity tungsten in a self-sacrificial process forms the interconnect structure, where the tungsten is in direct contact with the underlayer without an inserted layer.

This process results in an interconnect including tungsten and an inserted layer in contact with the underlayer, with the tungsten in the desirable alpha phase and with a highly oriented (110) microstructure with at least 95%, often at least 99% and even 100%, of the deposited tungsten thin film in the (110) crystalline orientation plane, relative to the top surface of the film. The grain size distribution can be such that the average grain size is at least five times, and more than ten times, which results in the low resistivity of tungsten.

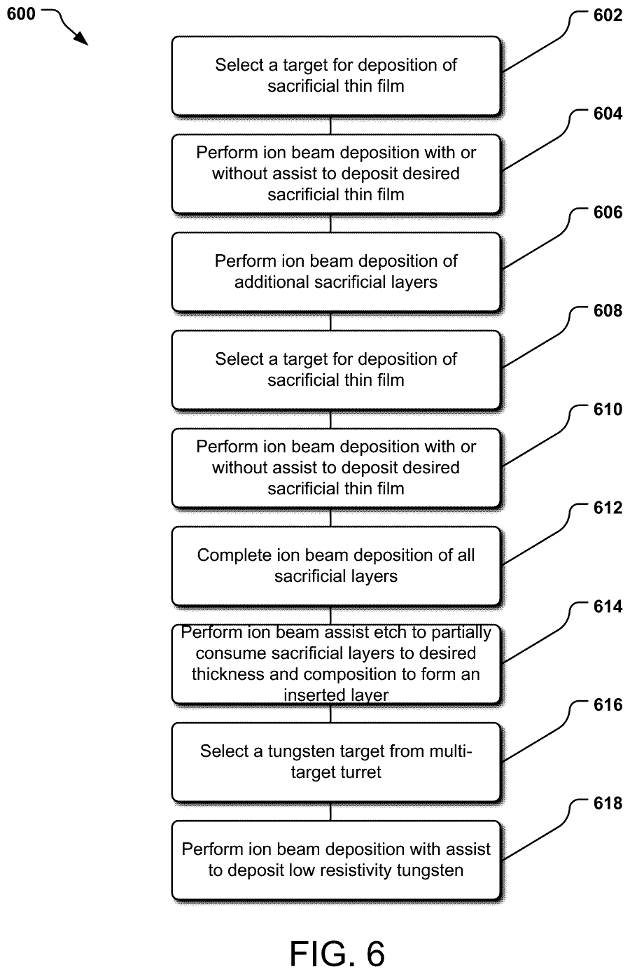

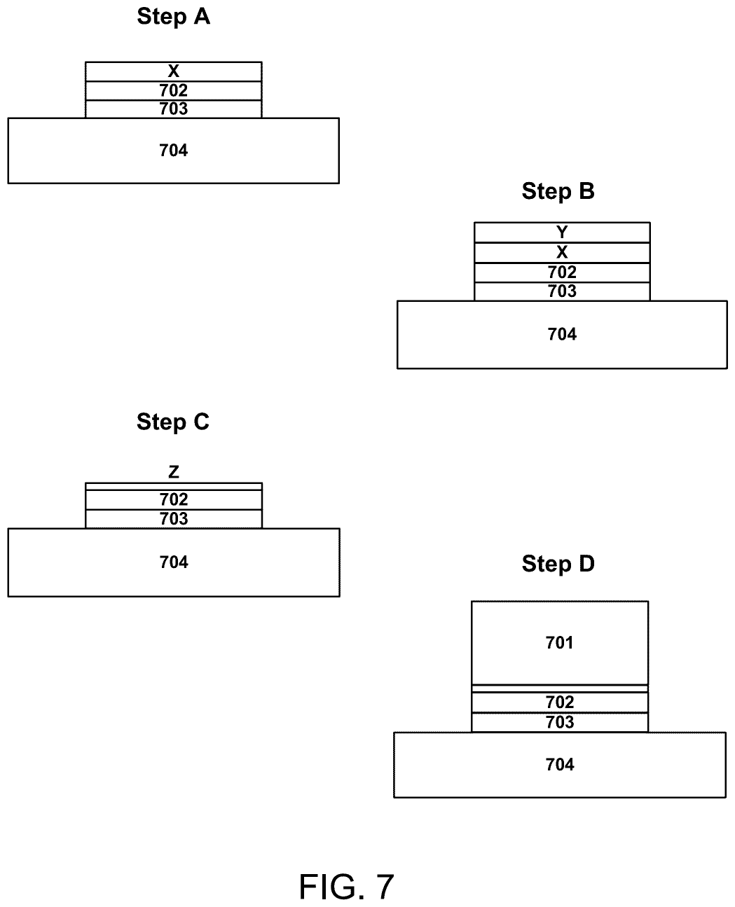

FIG. 6 describes, step by step, a method of making a structure such as the interconnect structures for memory and logic integrated circuits as described in FIG. 2B, FIG. 2C and FIG. 3B, FIG. 3C, and FIG. 7 illustrates schematically the configuration of the structures, step by step. The structures have a thin inserted layer between the low resistivity tungsten layer and the underlayer, with the inserted layer having the composition as deposited or modified to be different than the deposited inserted layer.

A multi-step method 600 for forming an interconnect structure is shown in FIG. 6. In a first step 602, a target in an IBD system is selected for use in depositing a sacrificial thin film; this target may be one of many targets in a multi-target turret. An ion beam deposition is done in step 604 to deposit the sacrificial thin film on a substrate; this may be done with or without assist. Any additional sacrificial layers or thin films can be deposited in step 606 in a manner similar to steps 602, 604.

In step 608, another target is selected for use in depositing another sacrificial thin film; this target may be one of many targets in the multi-target turret. An ion beam deposition is done in step 610 to deposit this sacrificial thin film on the previous sacrificial thin film(s) on the substrate; this may be done with or without assist. Any additional sacrificial layers or thin films can be deposited, and in step 612, all sacrificial layers having been deposited via ion deposition, with or without assist.

In step 614, ion beam assist etching is performed to partially remove portions of the sacrificial layer(s) to the desired thickness and to form the desired composition.

In step 616, a tungsten target is selected for use in depositing a tungsten thin film in step 618 with ion beam deposition with assist, and in step 618, ion beam deposition with assist is used to deposit a low resistivity tungsten film.

In FIG. 7, the evolution of a structure made via the method 600 of FIG. 6 is shown stepwise. In FIG. 7, layer 701 represents a tungsten layer, the layer 702 represents a desirable underlayer thin film, and the layer 703 represents other layers that are part of the device structure, such as a contact layer, for example, and structure 704 represents the device or structure in a DRAM memory cell or other type of memory cell or logic integrated circuit. Layers X and Y are sacrificial layers.

Referring to both FIGS. 6 and 7, the first step 602 selects a target material from the multi-target turret of the ion beam deposition chamber, the target material used to deposit the sacrificial thin film shown as layer X on the underlayer 702 in Step A of FIG. 7. The thickness of the sacrificial layer may be, e.g., as thin as 0.5 nm and as thick as 2 nm. Either a single sacrificial layer X or additional multiple sacrificial layers may be deposited, in accordance with step 606. For a single sacrificial layer X, the next step would be to proceed to the structure of Step C of FIG. 7. For additional sacrificial layers, the next step is to select another target material, as per step 608, from the multi-target turret of the ion beam deposition chamber and then deposit the sacrificial layer Y (per step 610) using ion beam deposition as shown in Step B. The thickness of the sacrificial layer may be, e.g., as thin as 0.5 nm and as thick as 2 nm.

The process used to deposit the sacrificial layers may be ion beam deposition using only the deposition ion beam or ion beam deposition with assist using both the deposition and assist ion beams. Ion beam energies of at least 50V to as high as 2000V can be used and ion beam current of at least 50 mA to as high as 2000 mA can be used.

After the sacrificial layers have been deposited as per step 612, the sacrificial layers are partially consumed (removed) using the assist ion beam in step 614, and as shown in Step C of FIG. 7, which etches the films and intermixes the atoms of the different layers. Ion beam energies of at least 50V to as high as 2000V can be used and ion beam current of at least 50 mA to as high as 2000 mA can be used, but are typically on the lower end for the consumption. The assist ion beam partially consumes the sacrificial layers X, Y by partial etching and intermixing and, in doing so, leaving behind an inserted layer Z having a thickness of as little as 0.1 nm to as thick as 2 nm. The inserted layer thickness can be modulated by adjusting the thicknesses of the sacrificial layers X, Y and the amount of consumption using the assist in step 614 and Step C of FIG. 7. If desired, a thicker inserted layer as thick as 3 nm or 4 nm or thicker can be created.

In some implementations, a single sacrificial layer is used to form the inserted layer. The assist etch partially consumes that inserted layer and modifies its composition to be different from the target. For example, for a sacrificial layer X deposited from a metal silicide target such as tungsten silicide, a thin tungsten silicide layer is deposited (e.g., least 0.1 nm but as thick as 2 nm or up to 5 nm) and by using the assist etch, is partially consumed. With appropriate combination of beam voltage and beam current of the assist etch, not only is the thickness of the tungsten silicide layer reduced by etching away but the etching and intermixing results in a change of the tungsten and silicon content from that of the target, resulting in in-situ composition adjustment of the layer that is then used to form the thin inserted layer.

In other implementations, multiple sacrificial layers are used to form the inserted layer and the process of using the assist etch to partially consume them modifies the composition to be different from the multiple targets used. For example, for a first sacrificial layer X, silicon is deposited from a silicon target and then a second sacrificial layer Y of tungsten is deposited from a tungsten target. The thicknesses of the layers may (independently) be at least 0.1 nm but as thick as 2 nm or up to 5 nm. Then, the assist etch with an appropriate combination of beam voltage and beam current partially consumes the sacrificial layers X, Y by etching and intermixing to leave behind an inserted layer Z of thickness at least 0.1 nm but as thick as 2 nm or up to 5 nm, the new layer Z being a compound of tungsten and silicon, such as a tungsten silicide, thereby creating a new material with a composition different from the targets chosen and thus creating a new in-situ material composition.

By varying the thicknesses of the different inserted layers and the amount of consumption using the assist etch, different compositions can be deposited. For example, a thicker tungsten layer compared to a thinner silicon layer would result in a tungsten rich tungsten silicide. By appropriate sequencing of the sacrificial layer deposition, choice of material of the sacrificial layers and thickness of the layers, inserted layers of different compositions can be created. Further the assist etch can be used to adjust the thickness of the inserted layer. In such a manner, an inserted layer is formed and adjusted in-situ.

The inserted layer can be composed of materials such as semiconductors such as silicon, metals such as titanium, tantalum, tungsten and others, dielectrics such as oxides including silicon oxide, tungsten oxide, and titanium oxide, nitrides such as silicon nitride, titanium nitride, and tungsten nitride, silicide-nitrides such as titanium silicon nitride, tungsten silicon nitride, and silicides such as tungsten silicide, titanium silicide and others.

Returning to FIG. 7, Step C shows the in-situ deposited inserted layer Z. In the next step 616, the tungsten target is selected from the multi-target turret of the ion beam chamber and used to deposit a tungsten thin film (step 618) using ion beam deposition with assist to the desired thickness, resulting in Step D. Ion beam energies of at least 50V to as high as 2000V can be used and ion beam current of at least 50 mA to as high as 2000 mA can be used.

This process of FIGS. 6 and 7 results in an interconnect including tungsten and an inserted layer having either a modified composition in contact with the underlayer, with the tungsten in the desirable alpha phase and with a highly oriented (110) microstructure with at least 95%, often at least 99% and even 100%, of the deposited tungsten thin film in the (110) crystalline orientation plane, relative to the top surface of the film. The grain size distribution can be such that the average grain size is at least five times, and more than ten times, which results in the low resistivity of tungsten.

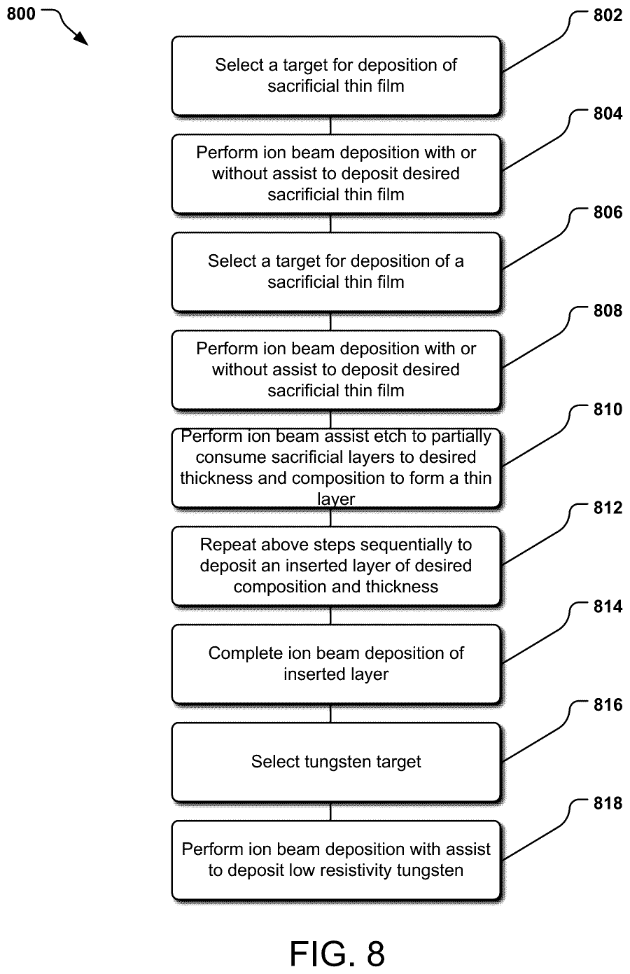

FIG. 8 describes, step by step, a sequence of making a structure such as the interconnect structures for memory and logic integrated circuits as described in FIG. 2D and FIG. 3D and FIG. 9 illustrates schematically the configuration of the structures, step by step. The structures have a thin inserted layer between the low resistivity tungsten layer and the underlayer, with the inserted layer having a graded or varied composition.

A multi-step method 800 for forming an interconnect structure is shown in FIG. 8. In a first step 802, a target in an IBD system is selected for use in depositing a sacrificial thin film; this target may be one of many targets in a multi-target turret. An ion beam deposition is done in step 804 to deposit the sacrificial thin film on a substrate; this may be done with or without assist. In step 808, another target is selected for use in depositing another sacrificial thin film; this target may be one of many targets in the multi-target turret. An ion beam etch is done in step 810 to partially remove portions of the sacrificial layer(s) to the desired thickness and to form the desired composition.

In step 812, the above steps 802 through 810 can be repeated to deposit a final inserted layer having the desired composition and thickness.

In step 816, a tungsten target is selected for use in depositing a tungsten thin film in step 818 with ion beam deposition with assist, and in step 818, ion beam deposition with assist is used to deposit a low resistivity tungsten film.

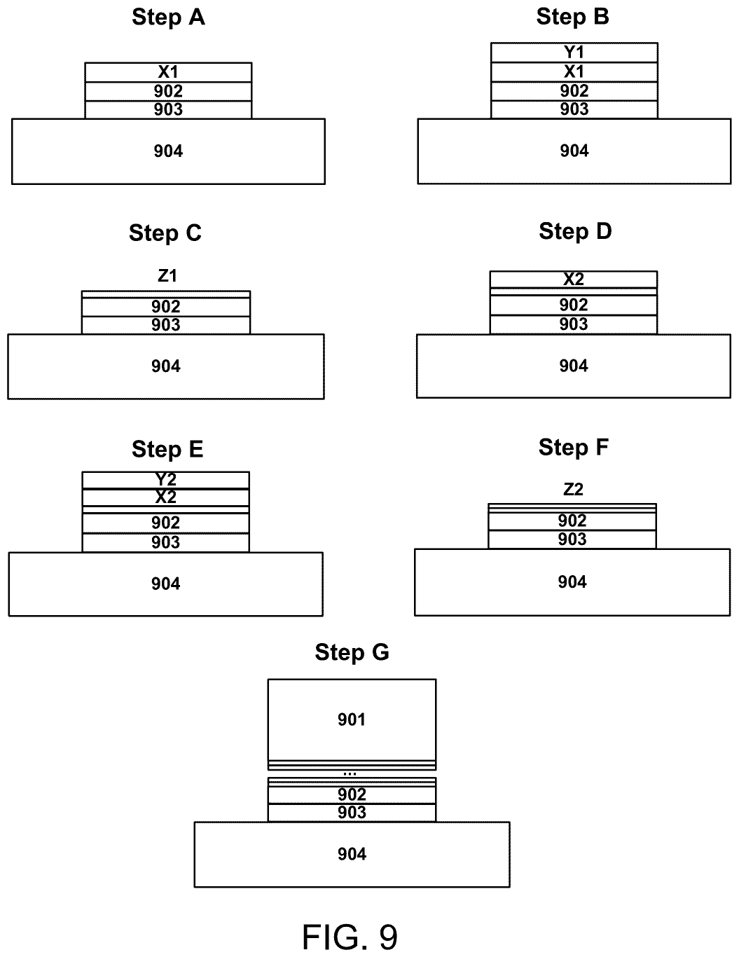

In FIG. 9, the evolution of a structure made via the method 800 of FIG. 8 is shown stepwise. In FIG. 9, layer 901 represents a tungsten layer, the layer 902 represents a desirable underlayer thin film, and the layer 903 represents other layers that are part of the device structure, such as a contact layer, for example, and structure 904 represents the device or structure in a DRAM memory cell or other type of memory cell or logic integrated circuit. Layers X and Y are sacrificial layers.

Referring to both FIGS. 8 and 9, the first step 802 selects a target material from the multi-target turret of the ion beam deposition chamber; the target material is used to deposit the sacrificial thin film layer X1 on the underlayer 902 of Step A in FIG. 9. The thickness of this sacrificial layer X1 may be, e.g., as thin as 0.5 nm and as thick as 2 nm. Either a single sacrificial layer or additional multiple sacrificial layers may be deposited. For a single sacrificial layer X1, the next step would be to proceed to Step C. For additional sacrificial layers above the layer X1, the next steps include selecting a target material per step 806 from the multi-target turret of the ion beam deposition chamber and then depositing the sacrificial layer Y1 using ion beam deposition as shown in Step B. The thickness of the sacrificial layer Y1 may be, e.g., as thin as 0.5 nm and as thick as 2 nm.

As with the previous methods described herein, the process used to deposit the sacrificial layers may be ion beam deposition using only the deposition ion beam or ion beam deposition with assist using both the deposition and assist ion beams. Ion beam energies of at least 50V to as high as 2000V can be used and ion beam current of at least 50 mA to as high as 2000 mA can be used.

After the sacrificial layers have been deposited per step 808, the sacrificial layers are partially consumed (removed) using the assist ion beam in step 810, which etches the films and intermixes the atoms of the different layers. Ion beam energies of at least 50V to as high as 2000V can be used and ion beam current of at least 50 mA to as high as 2000 mA can be used, but are typically on the lower end for the consumption. The assist ion beam consumes the sacrificial layers X1, Y1 by partial etching and intermixing and in doing so leaving behind an inserted layer Z1 (seen in Step C) of thickness as low as 0.1 nm to as thick as 2 nm. The inserted layer thickness can be modulated by adjusting the thicknesses of the sacrificial layers and the amount of consumption using the assist. If desired, a thicker inserted layer Z1, e.g., as thick as 3 nm or 4 nm or thicker, can be created. This sequence of steps (steps 808, 810) is repeated as step 812 to form sacrificial layers X2 and Y2 of Step D and Step E; step 814 results in an inserted layer Z2 shown in Step F.

By varying the thicknesses of the different layers X1, Y1 and X2, Y2 (etc.) and the amount of consumption using the assist etch, inserted layers of different compositions Z1, Z2, etc. can be deposited. By such a process, the composition of the layers Z is composed of the materials of layers X and Y, and by adjusting the thicknesses of the layers X and Y at each deposition step and the assist etch, the composition ratio of X:Y of the layers Z can be adjusted. By repeating the sequence as described, an inserted layer composed of multiple partially consumed layers Z can be deposited with the composition as determined by the constituents X:Y varying throughout the layer, forming a graduated compositional layer.

As an example, a compositionally graded tungsten silicide inserted layer can be created in-situ by such a process. First, a sacrificial layer of silicon is deposited from a silicon target followed by depositing a sacrificial layer of tungsten and using the assist etch to form a tungsten silicide inserted layer. By adjusting the thicknesses of the layers and the assist etch, the composition of this first inserted layer could be tungsten rich, for example. Next, this sequence is repeated but the thicknesses of the layer and assist etch are adjusted to increase the silicon content of the second inserted layer to result in a richer silicon content; this is continued until a final inserted layer that is silicon rich is deposited. The sum total of these inserted layers results in a composite inserted layer which has a graduated composition of tungsten and silicon from tungsten rich to silicon rich from the bottom to the top. By appropriate sequencing of the sacrificial layer deposition, choice of material of the sacrificial layers and thickness of the layers, an inserted layer of graduated composition can be created. Further the assist etch can be used to adjust the thickness of the inserted layer. Thus, this describes a method to form an in-situ inserted layer with graduated composition in-situ.

The inserted layer X, Y, Z can be composed of, e.g., semiconductors such as silicon, metals such as titanium, tantalum, tungsten and others, dielectrics such as oxides including silicon oxide, tungsten oxide, and titanium oxide, nitrides such as silicon nitride, titanium nitride, and tungsten nitride, silicide-nitrides such as titanium silicon nitride, tungsten silicon nitride, and silicides such as tungsten silicide, titanium silicide.

Returning to FIG. 8 and FIG. 9 Step G, the final low resistivity tungsten film 901 is deposited by selecting the tungsten target from the multi-target turret of the ion beam chamber (step 816) and using the tungsten target to deposit the tungsten thin film on the inserted layer Z2 using ion beam deposition with assist to the desired thickness (step 818). Ion beam energies of at least 50V to as high as 2000V can be used and ion beam current of at least 50 mA to as high as 2000 mA can be used.

This process of FIG. 8 and FIG. 9 results in a structure of the interconnect having tungsten and an inserted layer with graduated composition in contact with the underlayer and also results in the desirable alpha phase of the tungsten layer and a microstructure with highly oriented (110) grains with at least 95%, and up to the entire, of the deposited tungsten thin film having a (110) crystalline orientation plane, relative to the top surface of the film. The grain size distribution can be such that the average grain size is at least five times, and more than ten times, which results in the low resistivity of tungsten.

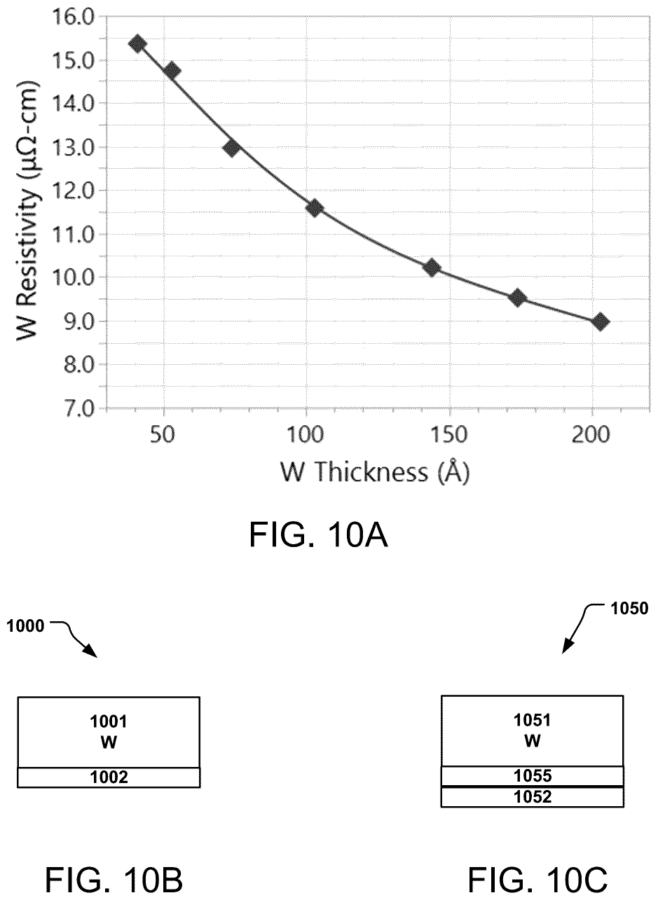

The interconnect structures of tungsten created using any of the above described methods have low resistivity. FIG. 10A shows resistivity versus tungsten thin film thickness for a structure having tungsten deposited on an underlayer without an inserted layer, made according to the methods of this disclosure. Such a structure is shown in FIG. 10B as interconnect structure 1000 having a tungsten layer 1001 directly on and in contact with an underlayer 1002.

With an inserted layer, however, the resistivity is significantly less. By including an inserted layer, such as made by the above methods, a thin tungsten interconnect structure can have a low resistivity at different thicknesses. FIG. 10C shows an interconnect structure 1050 having a tungsten layer 1051 and an underlayer 1052, with an inserted layer 1055 between and in contact with the layers 1051, 1052.

For example, an interconnect structure having an inserted layer between the tungsten layer and an underlayer can have a resistance less than 7 μΩ-cm for film thickness of 50 nm and thicker, less than 8 μΩ-cm for film thickness of 35 nm and thicker, less than 9 μΩ-cm for film thickness of 20 nm and thicker, less than 11 μΩ-cm for film thickness of 10 nm and thicker or less than 20 μΩ-cm for film thickness of 2 nm and thicker. Similar results for resistivity are achieved with thin inserted layers of adjusted compositions or graduated compositions.

From the foregoing, it will be appreciated that specific embodiments of the invention have been described herein for purposes of illustration, but that various modifications may be made without deviating from the scope of the invention. Accordingly, the invention is not limited except as by the appended claims.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

Various features and details have been provided in the multiple designs described above. It is to be understood that any features or details of one design may be utilized for or with any other design, unless contrary to the process, construction or configuration. Any variations may be made. For example, processing time, pressure, temperature, etc. may be varied.

The above specification and examples provide a complete description of the structure and use of exemplary implementations of the invention. The above description provides specific implementations. It is to be understood that other implementations are contemplated and may be made without departing from the scope or spirit of the present disclosure. The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about,” whether or not the term “about” is immediately present. Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass

implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

1. A method of forming a low resistivity interconnect structure, the method comprising:
depositing a tungsten film having a thickness no greater than 50 nm using ion beam deposition in a process chamber at a temperature of no more than 450° C. using a tungsten target held in a multi-target turret in the process chamber on an underlayer film,
the underlayer film being a metallic layer, a semiconducting layer, or a metal nitride layer.

2. The method of claim 1, further comprising:
prior to depositing the tungsten film, depositing an inserted layer on the underlayer film, the inserted layer comprising a metal, a semiconductor or a dielectric and having a thickness no greater than 50 Å.

3. The method of claim 2, wherein the inserted layer has a graduated composition.

4. The method of claim 1, wherein the underlayer film comprises titanium, tantalum, silicon, titanium nitride (TiN), silicon nitride (SiN), titanium silicon nitride (TiSiN), tungsten nitride (WN), tungsten silicon nitride (WSiN) or tantalum nitride (TaN).

5. The method of claim 4, wherein the underlayer film is deposited by physical vapor deposition (PVD), chemical vapor deposition (CVD), atomic layer deposition (ALD) or ion beam deposition (IBD).

6. The method of claim 1 further comprising:
prior to depositing the tungsten film, depositing a semiconductor, dielectric, or metal sacrificial layer on the underlayer using ion beam deposition in the process chamber using a target held in the multi-target turret.

7. The method of claim 6, wherein depositing the semiconductor, dielectric, or metal sacrificial layer comprises depositing multiple semiconductor, dielectric, or metal sacrificial layers.

8. The method of claim 7, wherein depositing multiple semiconductor, dielectric, or metal sacrificial layers comprises depositing the sacrificial layers from different targets in the multi-target turret.

9. The method of claim 8, wherein after depositing the multiple sacrificial layers, etching or intermixing the multiple sacrificial layers by bombarding at least some of the multiple sacrificial layers in the process chamber with an assist ion beam.

10. The method of claim 6 further comprising:
etching the sacrificial layer with an assist ion beam in the process chamber prior to depositing the tungsten film.

11. A tungsten film having a thickness and comprising:
a crystalline structure comprising alpha BCC grains having a (110) orientation; and
a mean grain size at least five times the thickness.

12. The tungsten film of claim 11, wherein the thickness is less than 50 nm.

13. The tungsten film of claim 11, wherein the tungsten film has a resistivity as a function of film thickness according to the following:
a resistivity in the range of 7-8 μΩ-cm for a thickness of 40-50 nm;
a resistivity in the range of 8-9 μΩ-cm for a thickness of 20-40 nm;
a resistivity in the range of 9-11 μΩ-cm for a thickness of 10-20 nm; and
a resistivity in the range of 11-20 μΩ-cm for a thickness of 1-10 nm.

14. The tungsten film of claim 11 having a thickness no greater than 50 nm and a resistivity in the range of 7-8 μΩ-cm.

15. The tungsten film of claim 11, wherein the film comprises at least 95% alpha BCC grains having the (110) orientation.

16. A low resistivity interconnect structure comprising:
a substrate;
an underlayer having a thickness less than 150 Å and comprising an electrically conducting metal, semiconductor or dielectric; and
a tungsten film having a thickness no greater than 50 nm and having a crystalline structure comprising alpha BCC grains having a (110) orientation, and an inserted layer present between the underlayer and the tungsten film, the inserted layer comprising a metal, a semiconductor or a dielectric and having a thickness no greater than 50 Å.

17. The structure of claim 16, wherein the inserted layer has a graduated composition.

18. The structure of claim 16, wherein a resistivity of the tungsten film as a function of the thickness can be described by the following:
a resistivity in the range of 7-8 μΩ-cm for a thickness of 40-50 nm;
a resistivity in the range of 8-9 μΩ-cm for a thickness of 20-40 nm;
a resistivity in the range of 9-11 μΩ-cm for a thickness of 10-20 nm; and
a resistivity in the range of 11-20 μΩ-cm for a thickness of 1-10 nm.

19. The structure of claim 16, wherein the structure is a memory structure or a logic structure.

20. The structure of claim 19, wherein the memory is a DRAM structure.
